(19) United States
(12) Patent Application Publication
(10) Pub. No.: US 2012/0077313 A1
(43) Pub. Date: Mar. 29, 2012

(54) SEMICONDUCTOR DEVICE MANUFACTURING METHOD

(75) Inventors: Soichi HOMMA, Kanagawa (JP); Taku Kamoto, Kanagawa (JP); Yuusuke Takano, Mie (JP); Masayuki Miura, Tokyo (JP)

(73) Assignee: KABUSHIKI KAISHA TOSHIBA, Tokyo (JP)

(21) Appl. No.: 13/235,417

(22) Filed: Sep. 18, 2011

(30) Foreign Application Priority Data
Sep. 24, 2010 (JP) 2010-213216

(51) Int. Cl. H01L 21/50

(52) U.S. Cl. 438/109; 438/106; 257/E21.499

(57) ABSTRACT

In a semiconductor device manufacturing method, a first resin layer with optical transmission restrained is formed on a supporting substrate and a second resin layer made of thermoplastic resin is formed on the first resin layer. An insulating layer and a wiring layer are formed on the second resin layer and a first semiconductor chip is mounted on the wiring layer. The supporting substrate is separated by irradiating the first resin layer with a laser beam, and the second resin layer is removed.

### CROSS-REFERENCE TO RELATED APPLICATIONS

This application is based upon and claims the benefit of priority from the prior Japanese Patent Application No. 2010-213216, filed on Sep. 24, 2010; the entire contents of which are incorporated herein by reference.

### FIELD

Embodiments described herein relate generally to a semiconductor device manufacturing method.

### BACKGROUND

Semiconductor devices include a so-called both surface mounted type with a plurality of semiconductor chips mounted on the both surfaces of a single substrate and a so-called single surface mounted type with semiconductor chips mounted on one surface and terminals on the other surface. In the above semiconductor devices which are manufactured using a thin film substrate, a substrate and a wiring layer are provided on a predetermined supporting substrate. Semiconductor chips are mounted on one surface of the substrate on the supporting substrate and then, the supporting substrate is separated from the substrate.

### BRIEF DESCRIPTION OF THE DRAWINGS

FIGS. 1 to 19 are views describing a semiconductor device manufacturing method according to the first embodiment;

FIG. 20 is a flow chart describing the semiconductor device manufacturing method according to the first embodiment;

FIGS. 21 to 28 are views describing a semiconductor device manufacturing method according to a second embodiment;

FIG. 29 is a flow chart describing the semiconductor device manufacturing method according to the second embodiment;

FIGS. 30 to 39 are views describing a semiconductor device manufacturing method according to a third embodiment;

FIG. 40 is a flow chart describing the semiconductor device manufacturing method according to the third embodiment;

FIG. 41 is a view illustrating a halfway process in the case of mold-sealing a plurality of semiconductor chips stacked; and

FIG. 42 is a view illustrating a semiconductor device with a semiconductor chip further FC-mounted on the rewired surface.

### DETAILED DESCRIPTION

In general, according to one embodiment, in a semiconductor device manufacturing method, a first resin layer having a restrained optical transmission is formed on a supporting substrate and a second resin layer made of thermoplastic resin is formed on the first resin layer. An insulating layer and a wiring layer are formed on the second resin layer and a first semiconductor chip is mounted on the wiring layer. The supporting substrate is separated by irradiating the first resin layer with a laser beam and the second resin layer is removed.

Exemplary embodiments of a semiconductor device manufacturing method will be explained below in detail with reference to the accompanying drawings. The present invention is not limited to the following embodiments.

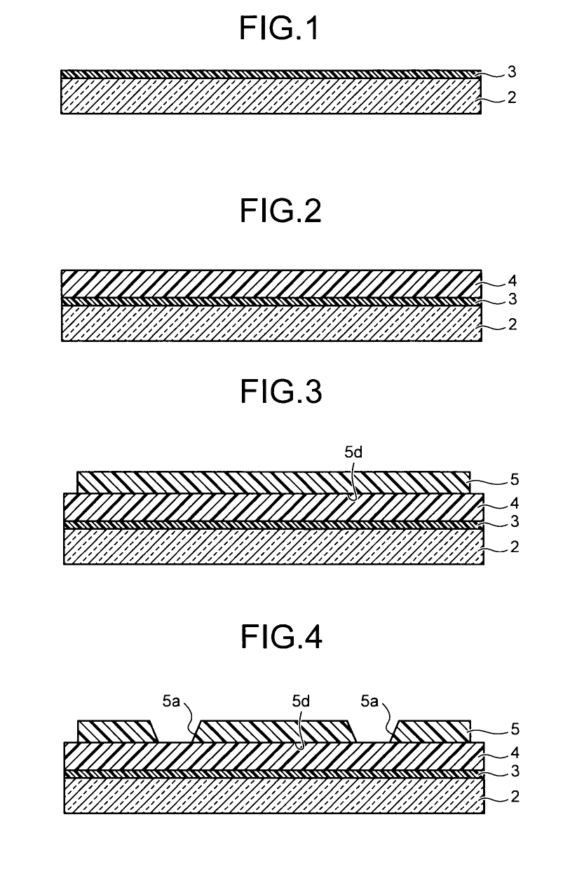

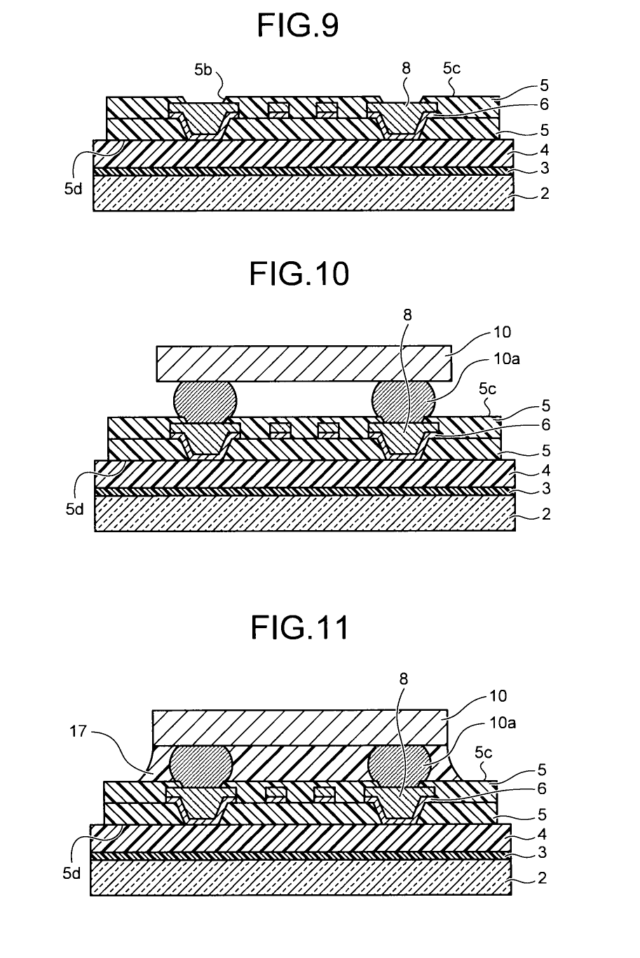

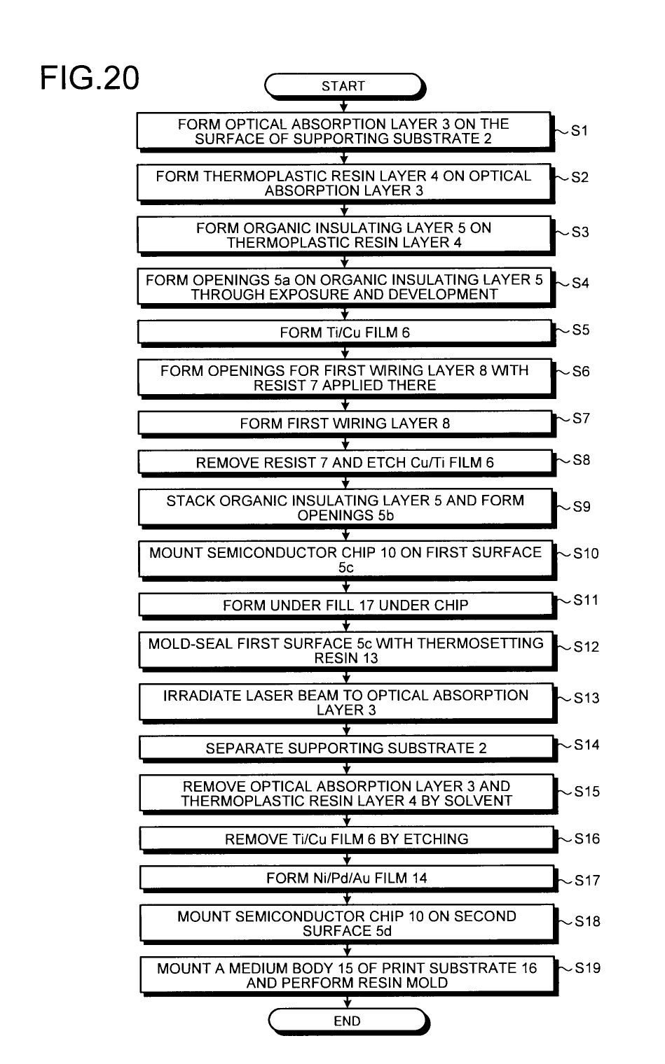

FIGS. 1 to 19 are views describing a semiconductor device manufacturing method according to a first embodiment. FIG. 20 is a flow chart describing the semiconductor device manufacturing method according to the first embodiment. In the following description, a surface of an organic insulating layer 5 on the side of a supporting substrate 2 is defined as a second surface 5d and the other surface thereof is defined as a first surface 5c (refer to FIG. 9).

At first, an optical absorption layer (first resin layer) 3 having a restrained optical transmission is formed on the surface of an 8-inch glass wafer that is the supporting substrate 2 (Step S1, also refer to FIG. 1). A mixture of transmission inhibitor for restraining optical transmission and synthetic resin is used for the optical absorption layer 3. The transmission inhibitor includes, for example, carbon black, graphite powder and iron, metal oxide such as titanium oxide, or dye and pigment. The optical absorption layer 3 is dissolved through irradiation of laser beam in the post process.

The optical absorption layer 3 is preferably formed with a thickness of not less than 0.1 μm and not more than 5 μm. For example, the optical absorption layer 3 is formed with a thickness of 1.5 μm. When the optical absorption layer 3 has a thickness of less than 0.1 μm, optical absorption is not effectively performed at the time of irradiation and the optical absorption layer 3 may not be dissolved well. When the optical absorption layer 3 has a thickness of more than 5 μm, a part of the optical absorption layer 3 cannot be dissolved and remains.

Next, a thermoplastic resin layer (second resin layer) 4 is formed on the optical absorption layer 3 (Step S2, also refer to FIG. 2). The thermoplastic resin layer 4 is formed with a thickness of not less than 1 μm and not more than 50 μm. For example, the thermoplastic resin layer 4 is formed with a thickness of 15 μm. For the thermoplastic resin layer 4, a synthetic resin may be used such as polystyrene, methacrylic resin, polyethylene, polypropylene, cellulose, polyamide, polyphenylene sulfide (PPS), polyether ether ketone (PEEK), liquid crystal polymer (LCP), polytetrafluoroethylene (PTFE), polyetherimide (PEI), polyarylate (PAR), polysulfone (PSF), polyether sulphon (PES), and polyamide imide (PAI). Here, when a mixture of transmission inhibitor for restraining optical transmission and the thermoplastic material is used as the optical absorption layer 3, the thermoplastic resin layer 4 on the optical absorption layer 3 can be saved.

When the thermoplastic resin layer 4 has a thickness of less than 1 μm, the optical absorption layer 3 may be damaged by the effect of the heat generated at irradiation of laser beam. When the thermoplastic resin layer 4 has a thickness of more than 50 μm, distortion may occur in the openings of the organic insulating layer 5 formed thereon.

A material with a glass transition temperature of not less than 150° C. and not more than 280° C. is used for the thermoplastic resin layer 4. When the glass transition temperature is less than 150° C., there occurs such a problem that the thermoplastic resin layer 4 is softened at a high temperature and that the openings of the organic insulating layer are distorted. As for a synthetic resin having a glass transition temperature of more than 280° C., the synthetic resin itself is difficult to manufacture.

Further, a material with a decomposition temperature of not less than 200° C. and not more than 400° C. is used for the thermoplastic resin layer 4. When the decomposition temperature is less than 200° C., the above layer 4 cannot resist a high temperature and it may be decomposed in the curing process of the organic insulating layer 5. Further, as for a resin having a decomposition temperature of more than 400° C., the synthetic resin itself is difficult to manufacture.

A material with an elasticity of not less than 0.01 GPa and not more than 10 GPa at a temperature of 25° C. is used for the thermoplastic resin layer 4. When the elasticity is less than 0.01 GPa, the openings of the organic insulating layer 5 may be distorted and tapered greatly because of the low elasticity. As for a synthetic resin with an elasticity of more than 10 GPa, a filler has to be put in the synthetic resin, which makes it difficult to form an opening.

Further, the coefficient of the thermal expansion CTE1 of the thermoplastic resin layer 4 should satisfy the range of “not less than CTE2×0.7 and not more than CTE2×1.3” with respect to the coefficient of the thermal expansion CTE2 of the organic insulating layer. When it is less than CTE2×0.7 or more than CTE2×1.3, the opening portions may be distorted easily when forming the organic insulating layer 5.

The thermoplastic resin layer 4 has to be formed selectively of a material resistant to a solvent included in the organic insulating layer 5. When a non-resistant material is used, the thermoplastic resin layer 4 is melt by the solvent included in the organic insulating layer 5 and mixed into the organic insulating layer 5 when forming the organic insulating layer 5, which makes it difficult to remove the resultant residual.

Next, the organic insulating layer (insulating layer) 5 of polyimide with a thickness of 3 μm is formed on the thermoplastic resin layer 4 (Step S3, also refer to FIG. 3). Further, the openings 5a are formed on the organic insulating layer 5 through exposure and development (Step S4, also refer to FIG. 4). The openings 5a are formed at the positions corresponding to the connection pads on the second surface 5d. The openings 5a are formed, for example, with a diameter of 20 μm and a pitch of 40 μm.

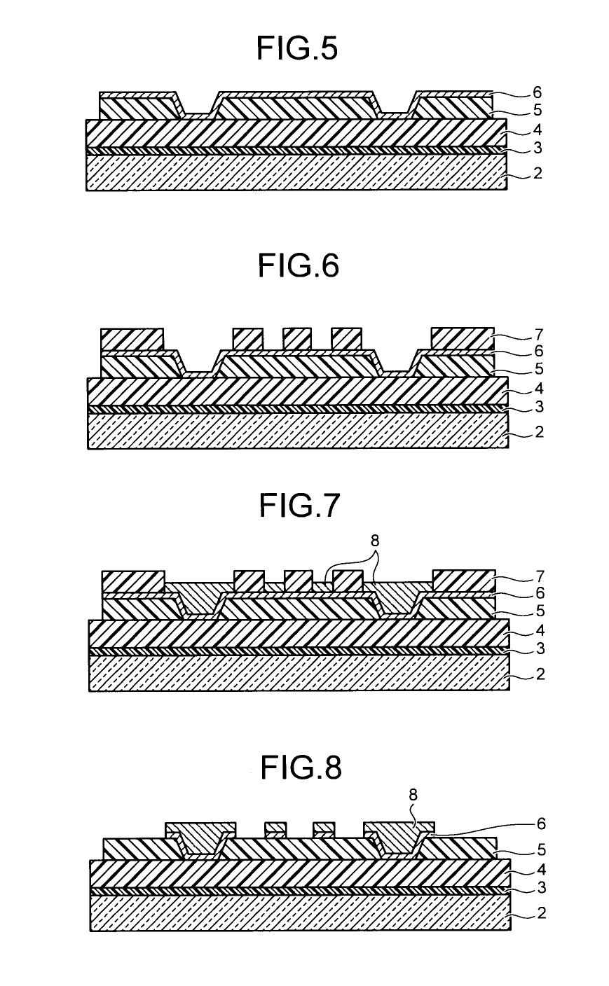

Next, a Ti/Cu film 6 is formed as a plating seed layer on the surface of the organic insulating layer 5, the inner lateral surface of the openings 5a, and the surface of the thermoplastic resin layer 4 bared as a result of forming the openings 5a (Step S5, also refer to FIG. 5). The Ti/Cu film 6 includes a Ti film with a thickness of 0.05 μm and a Cu film with a thickness of 0.1 μm.

A resist 7 with a thickness of 5 μm is applied on the Ti/Cu film 6 and openings for the first wiring layer (3 μm width) are formed through exposure and development (Step S6, also refer to FIG. 6). With the Ti/Cu film 6, that is the seed layer, used as an electrode, electrolytic Cu plating is performed, to form a first wiring layer 8 with a thickness of 3 μm (Step S7, also refer to FIG. 7).

Then, the resist 7 is removed and the Ti/Cu film 6 is etched (Step S8, also refer to FIG. 8). Of the Ti/Cu film 6, the Cu film is etched by a mixture of sulfuric acid and hydrogen peroxide water and the Ti film is etched by a mixture of ammonia water and hydrogen peroxide water.

With polyimide applied there, the organic insulating layer 5 is stacked, and openings 5b with a diameter of 20 μm (40 μm pitch) are formed at the positions corresponding to metal bumps 10a of a semiconductor chip 10 mounted on a first surface 5c as a first semiconductor chip (Step S9, also refer to FIG. 9). The semiconductor chip 10 is flip-chip mounted on the first surface 5c of the organic insulating layer 5 (Step S10, also refer to FIG. 10).

The metal bump 10a of the semiconductor chip 10 is formed of SnAg. Here, after a Ni/Pd/Au film is formed on the first wiring layer 8 bared as a result of forming the openings 5b, the SnAg bumps may be formed.

Besides the SnAg bump, Au, Sn, Ag, Cu, Bi, In, Ge, Ni, Pd, Pt, and Pb may be used for the metal bump 10a. Further, alloy or mixture of these metals may be used. The pitch of the metal bump 10a is 40 μm and the diameter thereof is 20 μm. In the FC bonding, flux is applied to the metal bumps 10a, they are mounted on the wiring pads by a flip chip bonder, and put into a reflow oven to be connected together, and then, the flux is removed by the cleaning liquid. Alternatively, instead of flux, oxide films of the SnAg bumps may be removed through plasma and they may be bonded by using a flip chip bonder through pulse heat. A plurality of semiconductor chips are flip-chip mounted on the first surface 5c of the organic insulating layer 5.

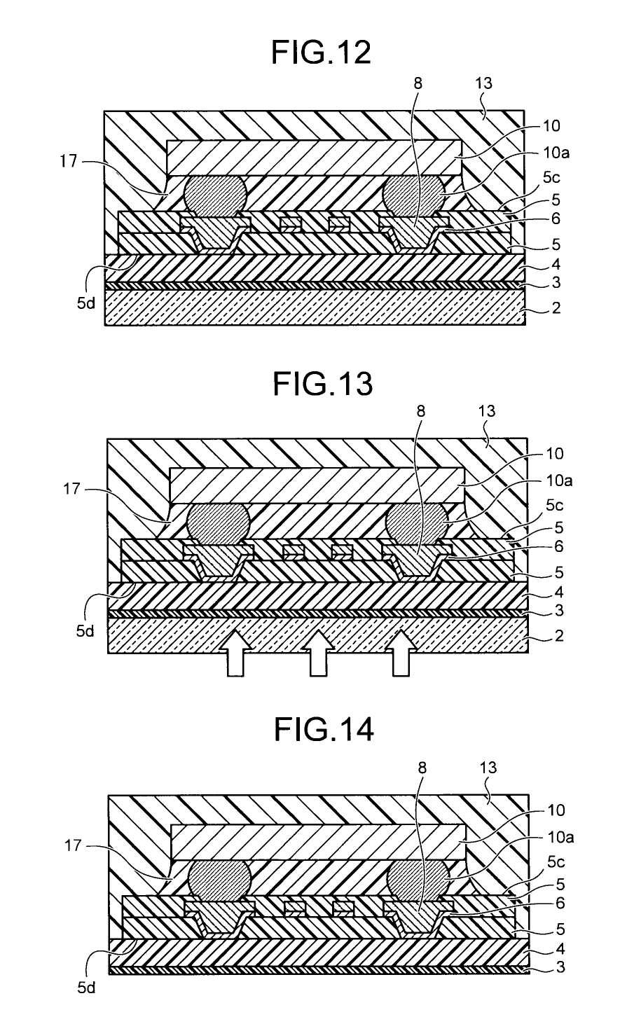

After the flip chip bonding of the semiconductor chip 10, resin is poured under the chips to form an under fill 17 (Step S11, also refer to FIG. 11), and the first surface 5c is mold-sealed with thermosetting resin 13 (Step S12, also refer to FIG. 12).

Laser beam is applied to the optical absorption layer 3 from the side of the supporting substrate 2 (Step S13, also refer to FIG. 13). The laser beam passes through the supporting substrate 2 and arrives at the optical absorption layer 3. Since the optical transmission is restrained in the optical absorption layer 3, the applied laser beam is absorbed and the temperature rises. According to this, as the optical absorption layer 3 is dissolved, the supporting substrate 2 is separated due to the optical absorption layer 3 (Step S14, also refer to FIG. 14). As the optical absorption layer 3 is dissolved, separating of the supporting substrate 2 can be smoothly performed and such a defect that a crack occurs in the organic insulating layer 5 can be inhibited.

As the laser beam to be applied, for example, YAG laser, ruby laser, excimer laser, CO₂ laser, He—Ne laser, Ar ion laser, and semiconductor laser can be used. Various wavelengths including infrared ray of wavelength 10.6 μm and 1064 nm, visible radiation of 694 nm, 633 nm, 532 nm, 514 nm, and 488 nm, and ultraviolet ray of 355 nm, 351 nm, 308 nm, and 248 nm can be used as the wavelength of the laser beam. Both continuous wave laser and pulse wave laser can be used.

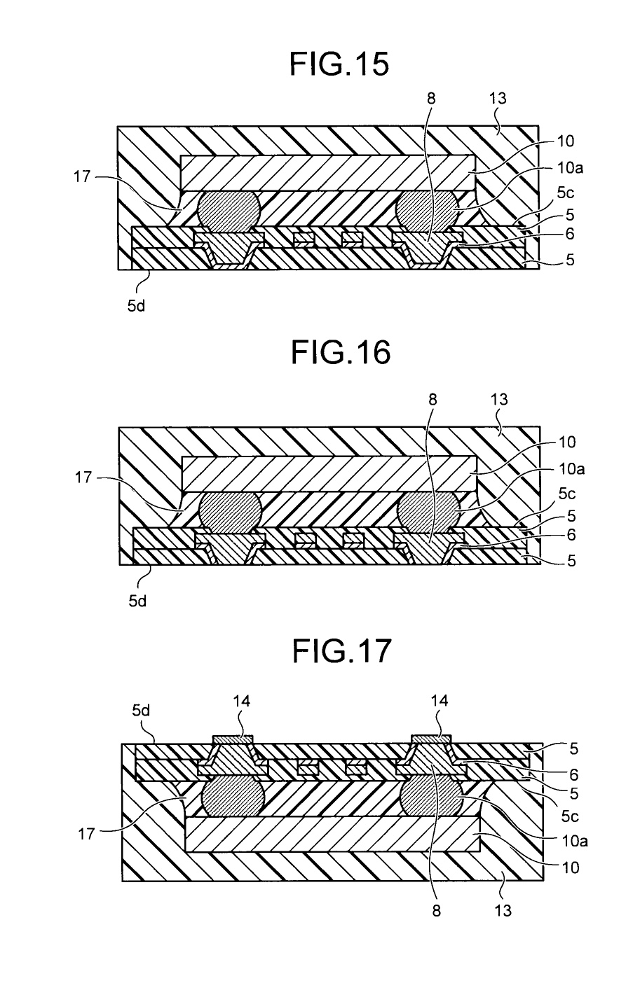

After separating the supporting substrate 2, the optical absorption layer 3 and the thermoplastic resin layer 4 are removed by the solvent such as acetone (Step S15, also refer to FIG. 15). Here, the thermoplastic resin layer 4 has to be resolved in the solvent. When there remains a residue, plasma may be applied to eliminate the residue.

After removing the optical absorption layer 3 and the thermoplastic resin layer 4, the Ti/Cu film 6 bared by the openings 5a of the organic insulating layer 5 is etched and removed (Step S16, also refer to FIG. 16). The Cu film is etched by a mixture of sulfuric acid and hydrogen peroxide water and the Ti film is etched by a mixture of ammonia water and hydrogen peroxide water.

As the Cu that becomes a connection pad is bared on the rear surface, a Ni/Pd/Au film 14 is formed on the above Cu surface through electroless plating (Step S17, also refer to FIG. 17). The Ni/Pd/Au film 14 includes Ni with a thickness of 3 μm, Pd with a thickness of 0.05 μm, and Au with a thickness of 0.5

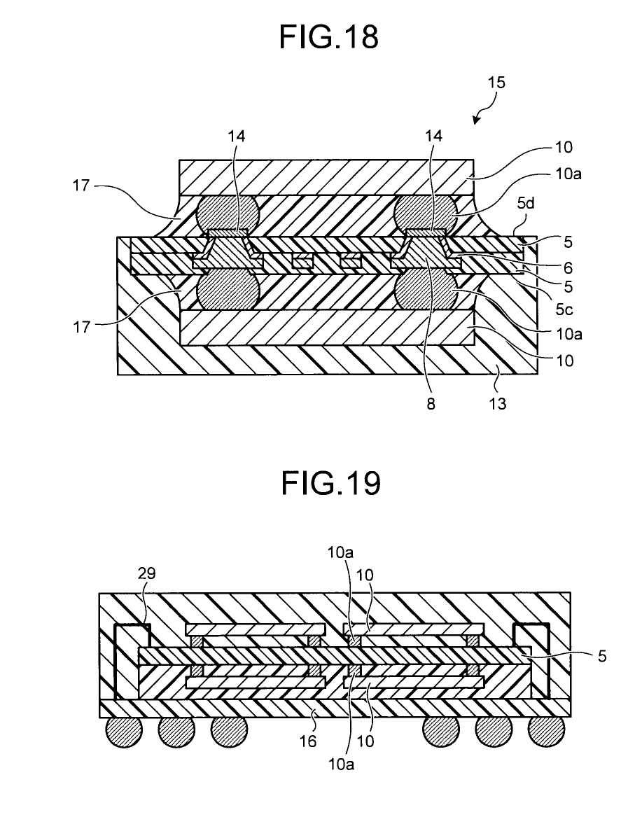

Similarly to the first surface 5c of the organic insulating layer 5, a semiconductor chip 10 as a second semiconductor chip is flip-chip mounted on the second surface 5d (Step S18, also refer to FIG. 18). According to the above processes, a medium body 15 of a semiconductor device is manufactured. Then, the medium body 15 is mounted on a print substrate 16 by a mount paste and wire-bonded on the print substrate 16 by an Au wire 29. Further, a resin mold is used to mount balls on the rear surface (Step S19, also refer to FIG. 19), hence to complete a semiconductor device.

According to the above processes, a semiconductor device was manufactured and tested in a temperature cycle test to check reliability thereof. The temperature cycle test was performed with one cycle of −55° C. (30 min) to 25° C. (5 min) to 125° C. (30 min). As the result, even after 3000 cycles, generation of break was hardly found on the first surface 5c and at the flip-chip connected position of the second surface.

As the organic insulating layer 5, besides polyimide, PBO (polybenzoxazole), phenol resin, and acrylic resin may be used. Although the Cu is used as the material of the first wiring layer 8, Al, Ag, and Au can be used. Although the wiring layer is formed with the glass as the supporting substrate 2, silicon and sapphire may be used. Namely, various kinds of materials can be used for the supporting substrate 2 as far as they can transmit a laser beam.

Although the embodiment shows the structure having only one first wiring layer 8, the wiring layer may be formed in a multilayer structure. When the wiring layer is formed in a multilayer structure, after the process of Step S8, the processes of Step S3 to Step S8 are repeated, to form a second wiring layer and a third wiring layer. For example, next to the process corresponding to Step S8, polyimide is further applied to stack the organic insulating layer, and at the same time, a Via layer is formed through exposure and development. A resist is applied with a thickness of 5 μm and openings of the second wiring layer (3 μm width) are formed through exposure and development. With the seed layer used as the electrode, electrolytic Cu plating is performed, to form a first wiring layer with a thickness of 3 μm. The resist is removed and the Cu film and the Ti film of the seed layer are etched. The Cu film is etched by a mixture of sulfuric acid and hydrogen peroxide water and the Ti film is etched by a mixture of ammonia water and hydrogen peroxide water.

Although the embodiment has been described taking a semiconductor device of a both surface mounted type as an example, it is not restricted to this. For example, the manufacturing method of the embodiment may be adapted to a semiconductor device of a single surface mounted type with the semiconductor chips mounted on one surface and the terminals formed on the other surface.

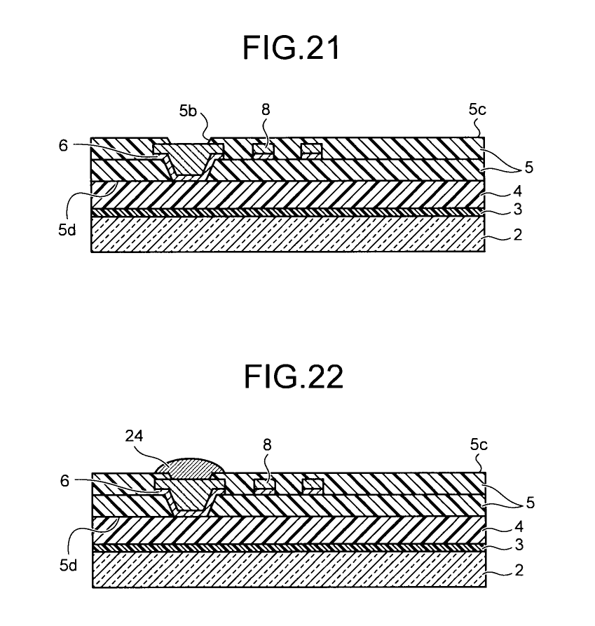

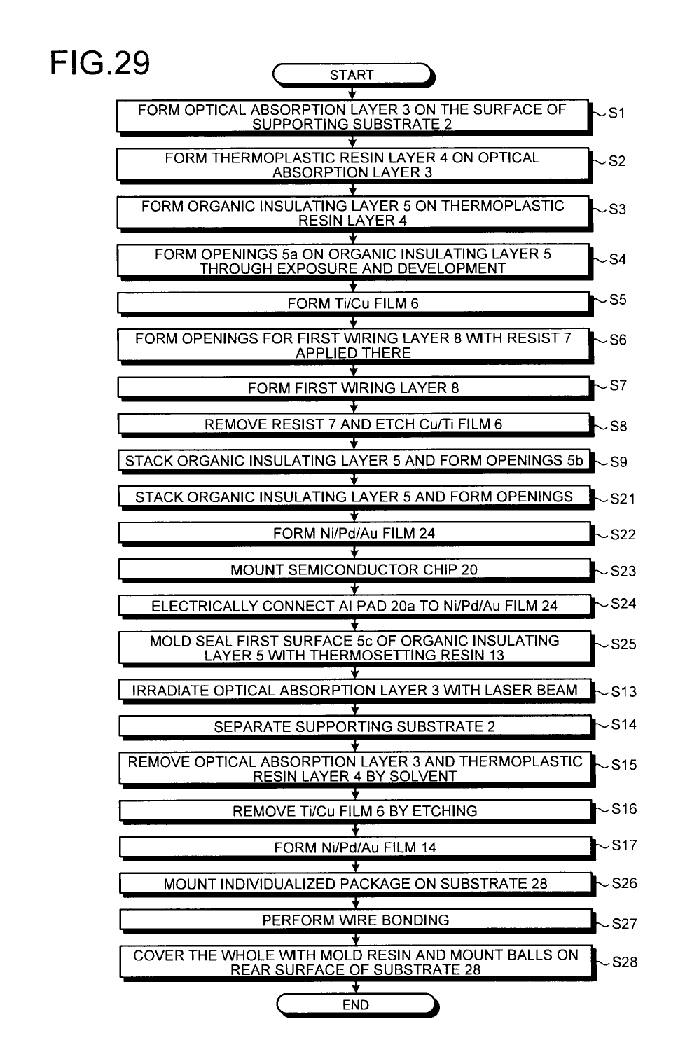

FIGS. 21 to 28 are views describing a semiconductor device manufacturing method according to a second embodiment. FIG. 29 is a flow chart describing the semiconductor device manufacturing method according to the second embodiment. The same reference numerals are attached to the same components as those of the first embodiment, to save the detailed description thereof.

The semiconductor device manufacturing method according to the second embodiment has the same procedure, up to Step S9, as that method having been described in the first embodiment, as illustrated in FIG. 29.

After the process of Step S9, an organic film such as polyimide is applied to stack the organic insulating layer 5 and openings each having a short side of 70 μm and a long side of 100 μm are formed at the positions corresponding to the connection pads on the first surface 5c with a pitch of 100 μm (Step S21, also refer to FIG. 21). Although the wiring layer of single layer has been described, needless to say, it may be formed in two layers or a multilayer structure.

Next, a Ni/Pd/Au film 24 is formed on the bared connection pad (Step S22, also refer to FIG. 22). The Ni/Pd/Au film 24 includes Ni with a thickness of 3 μm, Pd with a thickness of 0.05 μm, Au with a thickness of 0.5 μm through electroless plating.

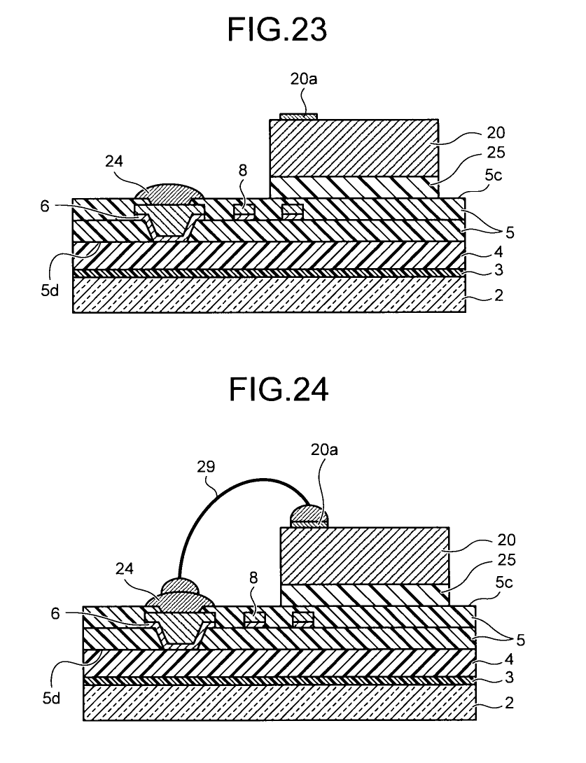

A semiconductor chip 20 is mounted on the organic insulating layer 5 using a mounting member 25 (Step S23, also refer to FIG. 23). For example, resin is used for the mounting member 25. The resin used for the mounting member 25 may be a liquid resin or film resin of epoxy, acrylic, and polyimide series. The semiconductor chip 20 used in the second embodiment is not provided with a metal bump 10a but with an Al pad 20a on the surface thereof. Therefore, the semiconductor chip 20 is not flip-chip mounted on the organic insulating layer 5 but mounted there using the mounting member 25.

The semiconductor chip 20 to be mounted on the organic insulating layer 5 may be one or stacked in two or more in a multistage. Next, the Al pad 20a of the mounted semiconductor chip 20 is electrically connected to the Ni/Pd/Au film 24 through wire bonding using the Au wire 29 (Step S24, also refer to FIG. 24).

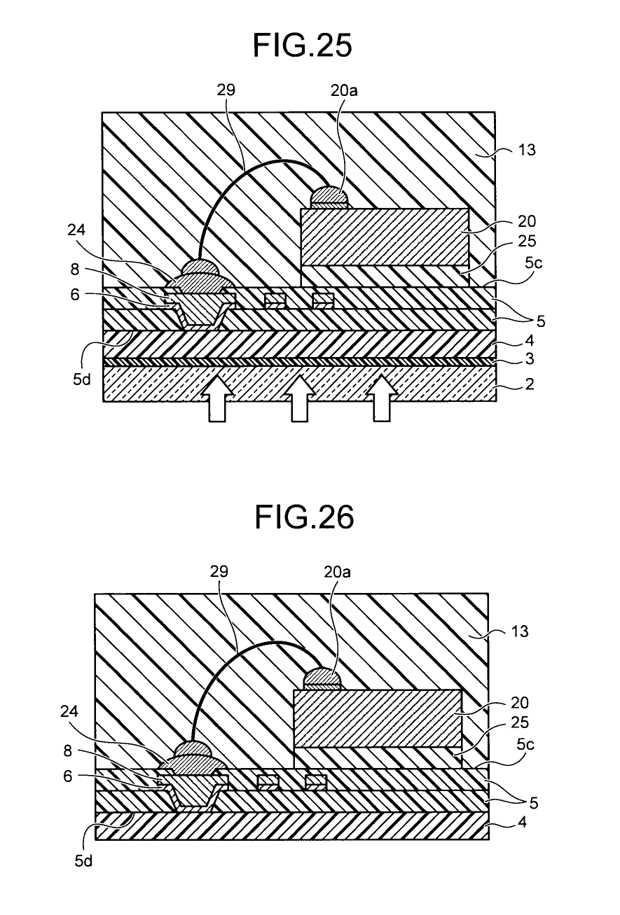

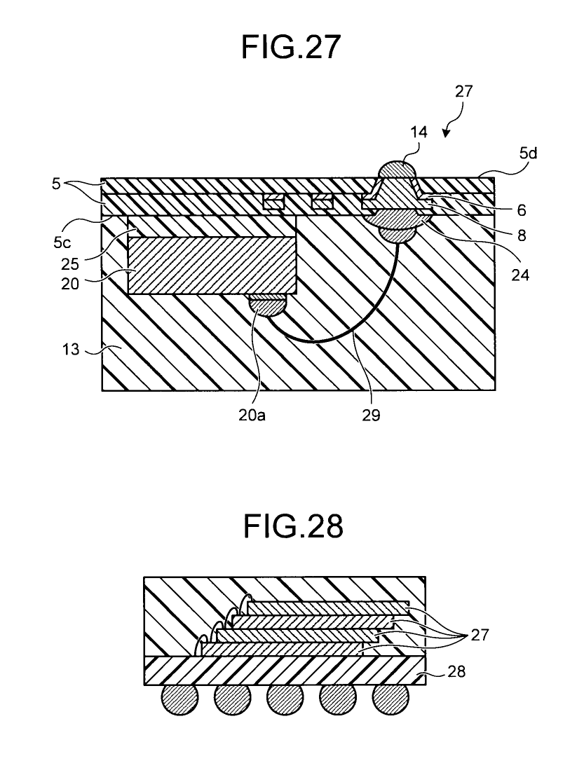

Next, the first surface 5c of the organic insulating layer 5 is mold-sealed by the thermosetting resin 13 (Step S25, also refer to FIG. 25). Similarly to the procedure having been described in the first embodiment, a resin body 27 is manufactured passing through the processes of Steps S13 to S17 (also refer to FIGS. 26 and 27).

This resin body is individualized through dicing and the individualized package is further mounted on the substrate 28 using a resin (Step S26). As illustrated in FIG. 28, the individualized packages may be stacked. The stacked packages are connected together through wire bonding (Step S27). The whole body is covered with the mold resin and balls are mounted on the rear surface of the substrate 28 (Step S28), hence to complete a semiconductor device.

According to the above-mentioned processes, a semiconductor device was manufactured and tested in a temperature cycle test to check reliability thereof. The temperature cycle test was performed with one cycle of −55° C. (30 min) to 25° C. (5 min) to 125° C. (30 min). As the result, even after 3000 cycles, generation of break was hardly found on the wire bonding portion. Because the electrode pad formed on the wiring layer gets smaller toward the separating layer and there is the mold resin around the outer periphery of the wiring layer, elasticity of the wiring layer can be restrained and a stress imposed on the electrode pad gets smaller, thereby hindering generation of a break between the electrode pad and the wiring at a time of reflow and TCT (Thermal Cycling Test).

As the organic insulating layer 5, besides polyimide, PBO (polybenzoxazole), phenol resin, and acrylic resin may be used. Although the Cu is used as the material of the first wiring layer 8, Al, Ag, and Au can be used. Although the wiring layer is formed with the glass as the supporting substrate 2, silicon and sapphire may be used. Namely, various kinds of materials can be used for the supporting substrate 2 as far as they can transmit a laser beam.

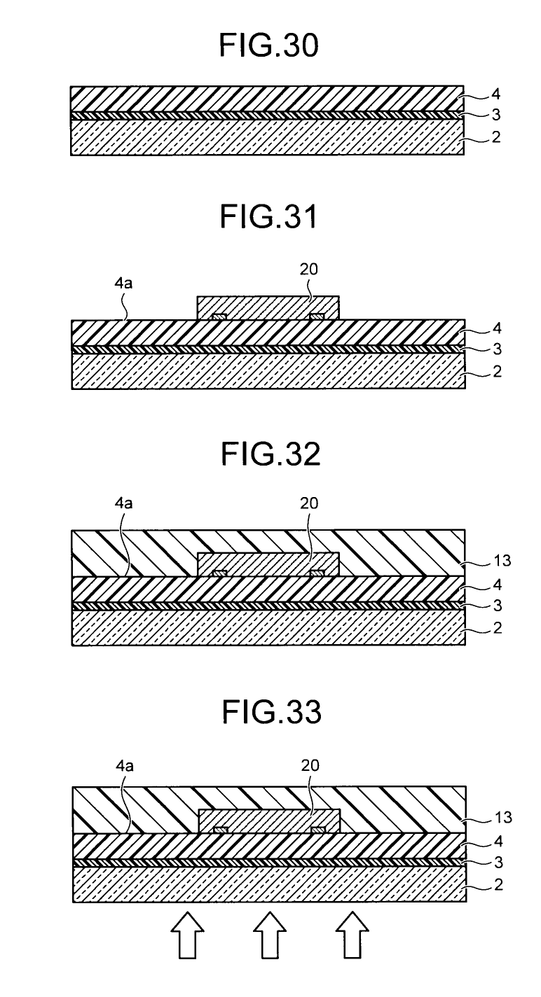

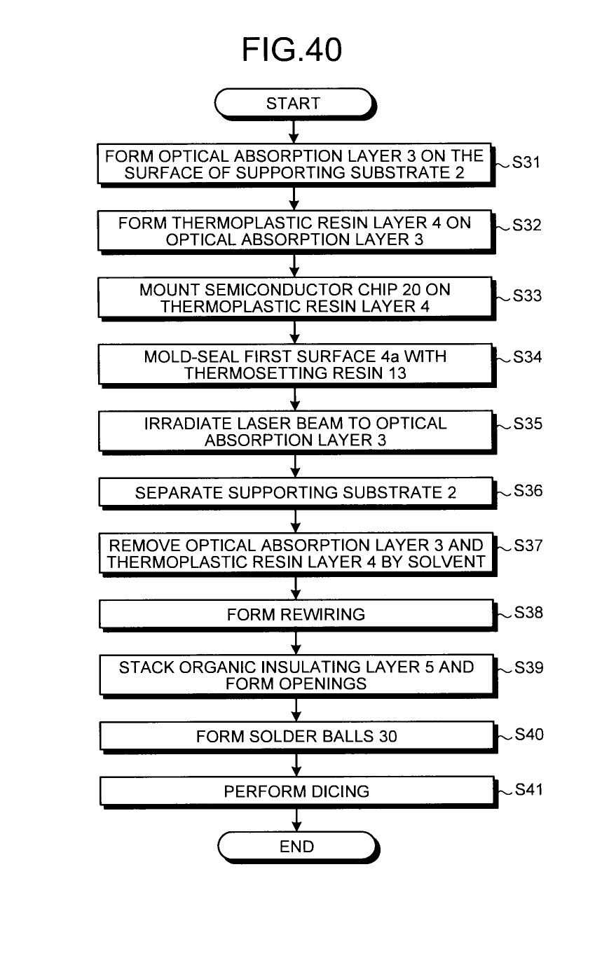

FIGS. 30 to 39 are views describing a semiconductor device manufacturing method according to a third embodiment. FIG. 40 is a flow chart describing the semiconductor device manufacturing method according to the third embodiment. The same reference numerals are attached to the same components as those of the above embodiments, to save the detailed description thereof.

At first, an optical absorption layer (first resin layer) 3 having a restrained optical transmission is formed on the surface of an 8-inch glass wafer that is the supporting substrate 2 (Step S31). A mixture of transmission inhibitor for restraining optical transmission and synthetic resin is used for the optical absorption layer 3. The transmission inhibitor includes, for example, carbon black, graphite powder and iron, metal oxide such as titanium oxide, or dye and pigment. The optical absorption layer 3 is dissolved through irradiation of laser beam in the post process.

The optical absorption layer 3 is preferably formed with a thickness of not less than 0.1 μm and not more than 5 μm. For example, the optical absorption layer 3 is formed with a thickness of 1.5 μm. When the optical absorption layer 3 has a thickness of less than 0.1 μm, optical absorption is not effectively performed at the time of irradiation of laser beam but the optical absorption layer 3 may not be dissolved well. When the optical absorption layer 3 has a thickness of more than 5 μm, a part of the optical absorption layer 3 cannot be dissolved but sometimes remains.

Next, a thermoplastic resin layer (second resin layer) 4 is formed on the optical absorption layer 3 (Step S32, also refer to FIG. 30). The thermoplastic resin layer 4 is formed with a thickness of not less than 1 μm and not more than 50 μm. For example, the thermoplastic resin layer 4 is formed with a thickness of 15 μm. For the thermoplastic resin layer 4, a synthetic resin may be used such as polystyrene, methacrylic resin, polyethylene, polypropylene, and cellulose.

When the thermoplastic resin layer 4 has a thickness of less than 1 μm, the optical absorption layer 3 may be damaged by the effect of the heat generated at irradiation of laser beam. When the thermoplastic resin layer 4 has a thickness of more than 50 μm, the semiconductor chip 20 to be mounted thereon may be easily deviated.

A material having a glass transition temperature of not less than 150° C. and not more than 280° C. is used for the thermoplastic resin layer 4. When the glass transition temperature is less than 150° C., the above layer is softened at a high temperature and the semiconductor chip 20 mounted thereon may be deviated easily. As for a synthetic resin having a glass transition temperature of more than 280° C., the synthetic resin is difficult to manufacture. A material having adhesive property is used for the thermoplastic resin layer 4.

The semiconductor chip 20 is aligned and mounted on the thermoplastic resin layer 4 as a first semiconductor chip (Step S33, also refer to FIG. 31). Next, a first surface 4a of the thermoplastic resin layer 4 with the semiconductor chip 20 mounted thereon is mold-sealed by the thermosetting resin 13 (Step S34, also refer to FIG. 32).

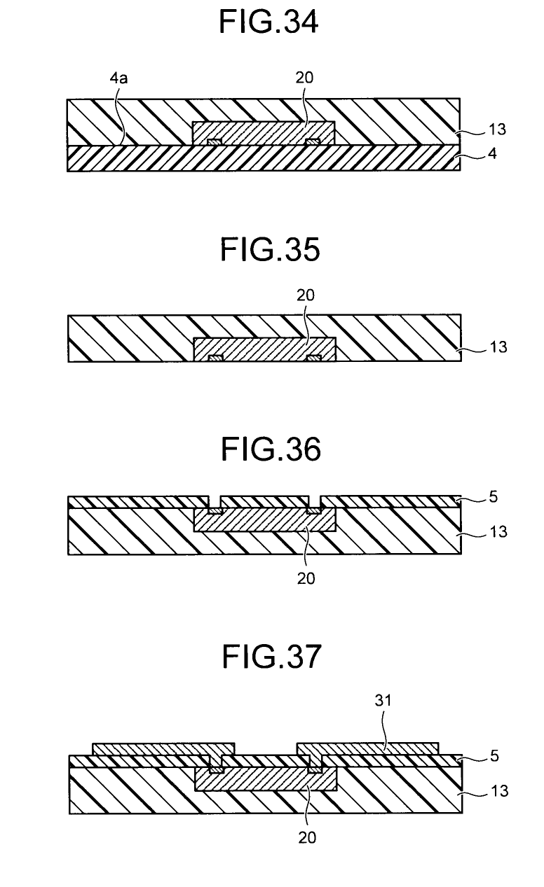

Laser beam is applied to the optical absorption layer 3 from the side of the supporting substrate 2 (Step S35, also refer to FIG. 33). The laser beam passes through the supporting substrate 2 and arrives at the optical absorption layer 3. Since the optical transmission is restrained in the optical absorption layer 3, the applied laser beam is absorbed and the temperature rises. According to this, as the optical absorption layer 3 is dissolved, the supporting substrate 2 is separated due to the optical absorption layer 3 (Step S36, also refer to FIG. 34). As the optical absorption layer 3 is dissolved, separating of the supporting substrate 2 can be smoothly performed.

As the laser beam to be applied, for example, YAG laser, ruby laser, excimer laser, CO₂ laser, He—Ne laser, Ar ion laser, and semiconductor laser can be used. Various wavelengths including infrared ray of wavelength of 10.6 μm and 1064 nm, visible radiation of 694 nm, 633 nm, 532 nm, 514 nm, and 488 nm, and ultraviolet ray of 355 nm, 351 nm, 308 nm, and 248 nm can be used as the wavelength of the laser beam. Both continuous wave laser and pulse wave laser can be used.

After separating the supporting substrate 2, the optical absorption layer 3 and the thermoplastic resin layer 4 are removed by the solvent such as acetone (Step S37, also refer to FIG. 35). Here, the thermoplastic resin layer 4 has to be resolved in the solvent. When there remains a residue, plasma may be applied to remove it.

Passing through the processes of Steps S36 and S37, since the pad of the semiconductor chip 20 is bared, rewiring is formed on this surface (Step S38). In the process of rewiring, for example, the organic insulating layer 5 is formed at first (also refer to FIG. 36). Then, openings are formed on the organic insulating layer 5. The openings are formed at the positions corresponding to the pad of the semiconductor chip 20. Next, a film of Ti/Cu is sputtered, a resist for forming the rewiring is formed, and the openings for wiring are formed. Then, the Cu plating is performed on the openings of the resist, the resist is removed, and the sputtered film is etched, thereby forming the rewiring 31 (refer to FIG. 37).

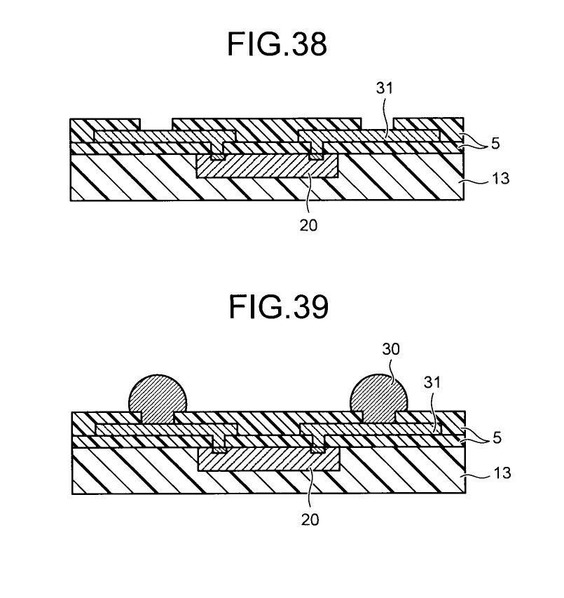

According to this, after forming the rewiring, the organic insulating layer 5 is stacked and the openings are formed (Step S39, also refer to FIG. 38). Solder balls 30 are formed in the opening portions (Step S40, also refer to FIG. 39). Further, dicing is performed (Step S41), hence to form a CSP of Fanout type.

According to the above processes, a semiconductor device was manufactured and tested in a temperature cycle test to check reliability thereof. The temperature cycle test was performed with one cycle of −55° C. (30 min) to 25° C. (5 min) to 125° C. (30 min). As the result, even after 3000 cycles, generation of break was hardly found on the re-wired portion.

When a rigidity of the thermoplastic resin layer 4 is short in forming the rewiring, a glass or metal plate may be attached to the thermoplastic resin layer 4 in order to raise the rigidity, hence to perform the process of the rewiring.

As the organic insulating layer 5, besides polyimide, PBO (polybenzoxazole), phenol resin, and acrylic resin may be used. Although the Cu is used as the material of the rewiring, Al, Ag, and Au can be used. Although the wiring layer is formed with the glass as the supporting substrate 2, silicon and sapphire may be used. Namely, various kinds of materials can be used for the supporting substrate 2 as far as they can transmit a laser beam.

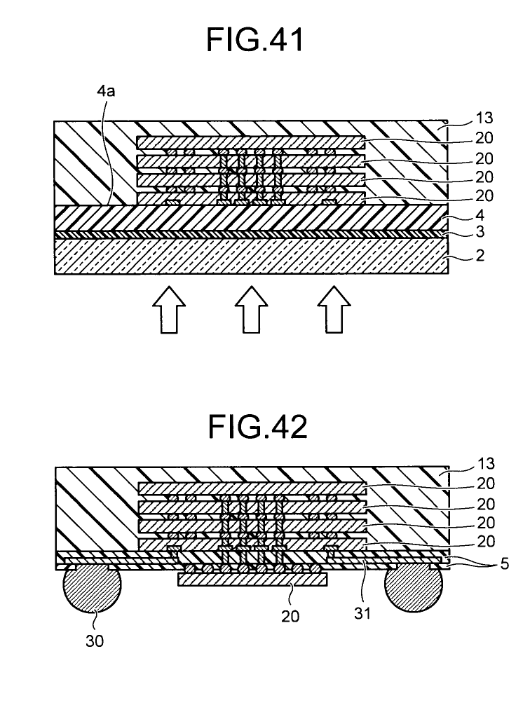

FIG. 41 is a view illustrating a halfway process in the case of mold-sealing a plurality of semiconductor chips 20 stacked. As illustrated in FIG. 41, there may be several semiconductor chips 20 to be mounted on the supporting substrate 2 (thermoplastic resin layer 4). Namely, the semiconductor chip 20 may be further stacked as a third semiconductor chip on the lowest first semiconductor chip. A stack of several semiconductor chips 20 being stacked in advance, for example, through TSV may be mounted there. Alternatively, chips for TSV may be stacked on the supporting substrate 2 (thermoplastic resin layer 4) one after another and FC-mounted there.

According to this, when the semiconductor chips 20 are previously stacked on the supporting substrate 2, the semiconductor chip 20 of the lowest layer, namely the semiconductor chip 20 directly mounted on the supporting substrate 2 (thermoplastic resin layer 4) can be mounted on the substantially plane supporting substrate 2. Accordingly, deflection hardly occurs in the semiconductor chip 20 of the lowest layer. When there is a deflection in the semiconductor chip 20, it is difficult to connect the semiconductor chips 20 to each other. Particularly, when the pitch of the bumps provided in the semiconductor chip 20 is fine and the semiconductor chip 20 has a deflection, the mutual connection is difficult. On the other hand, in the embodiment, since a deflection of the semiconductor chip 20 to be mounted can be restrained, the semiconductor chips 20 can be surely connected to each other.

FIG. 42 is a view illustrating a semiconductor device in which the semiconductor chip 20 is further FC-mounted on the rewired surface. As illustrated in FIG. 42, after the process of the rewiring of Step S38, the semiconductor chip 20 is FC-mounted on the rewired surface as a fourth semiconductor chip, thereby forming a semiconductor device.

While certain embodiments have been described, these embodiments have been presented by way of example only, and are not intended to limit the scope of the inventions. Indeed, the novel methods described herein may be embodied in a variety of other forms; furthermore, various omissions, substitutions and changes in the form of the methods described herein may be made without departing from the sprit of the inventions. The accompanying claims and their equivalents are intended to cover such forms or modifications as would fall within the scope and spirit of the inventions.

What is claimed is:

1. A semiconductor device manufacturing method comprising:
forming a first resin layer with optical transmission restrained on a supporting substrate;
forming a second resin layer made of thermoplastic resin on the first resin layer;
forming an insulating layer and a wiring layer on the second resin layer;
mounting a first semiconductor chip on the wiring layer;
separating the supporting substrate by irradiating the first resin layer with a laser beam; and
removing the second resin layer.

2. The semiconductor device manufacturing method according to claim 1, further comprising:
forming an interlayer connecting body electrically conducted by the wiring layer within the insulating layer; and
mounting a second semiconductor chip on a surface bared by the removal of the second resin layer so that the second semiconductor chip is electrically connected to the interlayer connecting body.

3. The semiconductor device manufacturing method according to claim 1, wherein
the supporting substrate is formed of optical translucent material, and
the laser beam is irradiated to the first resin layer through the supporting substrate.

4. The semiconductor device manufacturing method according to claim 1, wherein
the first resin layer is formed of a mixture of transmission inhibitor for restraining optical transmission and synthetic resin.

5. The semiconductor device manufacturing method according to claim 4, wherein
the transmission inhibitor is carbon black.

6. The semiconductor device manufacturing method according to claim 4, wherein
the transmission inhibitor is metal oxide.

7. The semiconductor device manufacturing method according to claim 1, wherein
the removal of the second resin layer is performed by application of plasma.

8. The semiconductor device manufacturing method according to claim 1, wherein
the laser beam is YAG laser.

9. The semiconductor device manufacturing method according to claim 1, wherein
the second resin layer is formed of a material that is resistant to a solvent included in the insulating layer.

10. The semiconductor device manufacturing method according to claim 1, comprising
forming an under fill by pouring a resin between the second semiconductor chip and the insulating layer.

11. A semiconductor device manufacturing method comprising:
forming a first resin layer with optical transmission restrained on a supporting substrate;
forming a second resin layer made of thermoplastic resin on the first resin layer;
mounting a first semiconductor chip on the second resin layer;
separating the supporting substrate by irradiating the first resin layer with a laser beam; and
removing the second resin layer.

12. The semiconductor device manufacturing method according to claim 11, wherein
the supporting substrate is formed of optical translucent material, and
the laser beam is irradiated to the first resin layer through the supporting substrate.

13. The semiconductor device manufacturing method according to claim 11, wherein
the first resin layer is formed of a mixture of transmission inhibitor for restraining optical transmission and synthetic resin.

14. The semiconductor device manufacturing method according to claim 13, wherein
the transmission inhibitor is carbon black.

15. The semiconductor device manufacturing method according to claim 13, wherein
the transmission inhibitor is metal oxide.

16. The semiconductor device manufacturing method according to claim 11, wherein
the removal of the second resin layer is performed by application of plasma.

17. The semiconductor device manufacturing method according to claim 11, wherein
the first semiconductor chip is mounted in such a way that a pad of the first semiconductor chip is in touch with the second resin layer, and
the pad is bared by removing the second resin layer.

18. The semiconductor device manufacturing method according to claim 11, wherein
the laser beam is YAG laser.

19. The semiconductor device manufacturing method according to claim 11, comprising
mold-sealing a first surface of the second resin layer with the first semiconductor chip mounted thereon by a thermosetting resin and then separating the supporting substrate.

20. The semiconductor device manufacturing method according to claim 13, comprising
stacking a third semiconductor chip on the first semiconductor chip and then separating the supporting substrate.
